(19) United States
(12) Patent Application Publication
(10) Pub. No.: US 2018/0358225 A1
(43) Pub. Date: Dec. 13, 2018

(54) METHOD FOR PRODUCING COMPLIMENTARY DEVICES

(71) Applicant: Lars-Erik WERNERSSON, LUND (SE)

(72) Inventors: Lars-Erik Wernersson, Lund (SE); Johannes Svensson, LUND (SE); Anil Dey, Portland, OR (US)

(21) Appl. No.: 15/562,098

(22) PCT Filed: May 27, 2016
(86) PCT No.: PCT/EP2016/062049

§ 371 Date: Sep. 27, 2017

(30) Foreign Application Priority Data
Mar. 27, 2015 (SE) 1500156-3

(51) Int. Cl. H01L 21/02; H01L 27/092; H01L 29/06; H01L 29/205; H01L 29/423; H01L 29/775; H01L 21/8238

(52) U.S. Cl. CPC H01L 21/02381; H01L 21/02653; H01L 29/0676; H01L 29/068; H01L 29/205; H01L 29/42392; H01L 29/775; H01L 21/823807; H01L 21/823885; H01L 21/02463; H01L 21/02546; H01L 21/02549; H01L 21/02576; H01L 21/02579; H01L 21/02603; H01L 21/02645; H01L 27/092

(57) ABSTRACT

A method for fabrication of growing, in one growth run, at least one group of III-V n-type nanowires and at least one group of III-V p-type nanowires using gold particles, where the gold particles are of one size for the III-V n-type nanowires and one size for the III-V p-type nanowires.

### TECHNICAL FIELD

The present invention relates in general to the integration of complimentary semiconductor devices on Si substrates using epitaxial techniques. These devices, or transistors, are key components for the implementation of logic functions, memory elements, or RF-components in various types of hardware including laptops, portable electronics, data servers, and wireless sensors. In particular, the invention relates to the integration of III-V materials and devices on silicon (Si) substrates that will reduce cost and increase manufacturability.

### BACKGROUND

Geometrical scaling has for decades been the main technology drive for integrated Si circuits. In the latest technology generations, however, integration of novel materials has played an important role in the continued technology evolution. For future generations, III-V semiconductors, such as (InAs, InGaAs, GaAs, InP, GaSb, GalnSb, InSb) are considered candidates to replace Si as the channel material in metal-oxide-semiconductor field-effect transistors (MOSFETs) due to their high mobility and injection velocity that will enable voltage scaling to reduce the power consumption at maintained performance. For competitiveness, both n- and p-type transistors need to be integrated on a Si substrate, however, the large lattice mismatch of III-V materials both to Si, and between materials suitable for n- and p-type transistors makes planar epitaxial growth challenging. Previous efforts to integrate III-V materials on a Si platform have involved either transfer of channel material grown on a separate substrate or have exploited growth techniques, such as aspect ratio trapping, to avoid high defect densities. Dry transfer techniques have been used as one alternative to integrate two different III-V materials on the same platform, but such methods are not suitable for large scale manufacturing. Thus, methods for co-integration of III-V materials on Si to reduce cost and increase the manufacturability are highly sought after.

### SUMMARY OF THE INVENTION

Using a novel approach to grow both InAs and InAs/GaSb nanowires simultaneously in a single growth run, we here demonstrate n- and p-type, vertical III-V nanowire MOSFETs monolithically integrated on a Si substrate. Nanowire growth enables high III-V crystal quality grown directly on e.g. Si, as strain may relax radially. The technology may be used to demonstrate fundamental CMOS logic gates, such as inverters and NAND gates, and illustrates the viability of our approach for large scale III-V circuits on Si. In addition, it may be used for RF devices and axial Tunnel Field-Effect Transistors (pTFETs) formed at the InAs/GaSb heterojunction.

With the above description in mind, then, an aspect of some embodiments of the present invention is to provide a technology, which seeks to mitigate, alleviate or eliminate one or more of the above-identified deficiencies in the art and disadvantages singly or in any combination.

An aspect of the present invention relates to a method for fabrication of at least two groups of nanowires in one growth run, comprising the steps of, providing a silicon platform and growing, in one growth run, at least one group of III-V n-type nanowires and at least one group of III-V p-type nanowires using gold particles, wherein said gold particles are of one size for the III-V n-type nanowires and one size for the III-V p-type nanowires.

Another aspect of the present invention relates to a method for fabrication of at least two groups of nanowires, comprising the steps of providing a silicon platform, providing at least two gold discs on said silicon platform, covering at least one of said discs with a dielectric film, making an opening in said dielectric film of at least one of said discs, growing at least one group of either III-V n-type nanowires or at least one group of III-V p-type nanowires using said gold discs, remove said dielectric film, provide at least one gold seed to said at least one group of n-type nanowires or said at least one group of p-type nanowires and growing at least one group of either III-V n-type nanowires or at least one group of III-V p-type nanowires using said at least one gold seed.

The method may further comprise that said silicon platform is comprised of a p-type Si substrate.

The method may further comprise the step of providing an InAs layer on said silicon platform.

The method may further comprise that said gold particles have a diameter in the range of 3 to 100 nm.

The method may further comprise that at least one group of n-type nanowires and said at least one group of p-type nanowires are grown to the same height in the range of 10 nm to 1000 nm.

The method may further comprise placing at least one metal gate in contact with at least one nanowire in one of said at least one group of n-type nanowires or said at least one group of p-type nanowires.

The method may further comprise placing at least one metal gate in contact with at least one nanowire in said at least one group of n-type nanowires and at least one nanowire in said at least one group of p-type nanowires.

The method may further comprise that said at least one group of n-type nanowires are n-InAs nanowires and wherein said at least one group of p-type nanowires are p-GaSb nanowires

The method may further comprise providing an III-V semiconductor shell around at least one p-type nanowire in said at least one group of p-type nanowires.

The method may further comprise that said III-V semiconductor shell is comprised of InGaAs and/or GalnAsSb.

The method may further comprise that said nanowires are axial heterostructure nanowires.

Yet another aspect of the present invention relates to a semiconductor device comprising at least one group of III-V n-type nanowires and at least one group of III-V p-type nanowires wherein said at least one group of n-type nanowires and at least one group of p-type nanowires are growing in one growth run.

Yet another aspect of the present invention relates to a semiconductor device comprising at least one group of III-V n-type nanowires and at least one group of III-V p-type nanowires wherein said at least one group of n-type nanowires and at least one group of p-type nanowires are grow comprising the steps of providing a silicon platform, providing at least two gold discs on said silicon platform, covering at least one of said discs with a dielectric film, making an opening in said dielectric film of at least one of said discs, growing at least one group of either III-V n-type nanowires or at least one group of III-V p-type nanowires using said gold discs, remove said dielectric film, provide at least one gold seed to said at least one group of n-type nanowires or said at least one group of p-type nanowires and growing at least one group of either III-V n-type nanowires or at least one group of III-V p-type nanowires using said at least one gold seed.

The features of the above-mentioned embodiments can be combined in any combinations.

### BRIEF DESCRIPTION OF THE DRAWINGS

Further objects, features and advantages of the present invention will appear from the following detailed description of the invention, wherein embodiments of the invention will be described in more detail with reference to the accompanying drawings, in which:

FIG. 1. Schematic growth process for monolithic integration of InAs and GaSb nanowires on a Si substrate. (a) Au particles of different sizes are patterned by EBL on a Si substrate with a highly doped InAs layer. (b) InAs and InAs/GaSb nanowires are grown from the Au particles that act as growth seeds. The particle size and pitch is used to adjust the growth rate so that a similar total length of both types of nanowires is obtained. The differently doped segments and the position of the gate electrode are indicated in the figure.

FIG. 2. SEM micrograph of InAs and GaSb nanowire arrays on Si.

FIG. 3. Output characteristics of InAs and GaSb MOSFETs. The InAs MOSFET has 588 wires with d_{InAs}=32 nm and the GaSb pTFET has 13 wires with d_{GaSb}=48 nm. The gate voltage is −0.5 V<V_{gs}<0.5 V for InAs and 1 V>V_{gs}>−0.5 V for GaSb with 100 mV steps.

FIG. 4. Output characteristics of a forward biased InAs/GaSb pTFET with V_{g} from 0.5 to −0.9 V (0.1 V steps) clearly displaying negative differential resistance characteristics indicating a tunneling transport mechanism at room temperature.

FIG. 5. AC and DC inverter and NAND characteristics. (a) VTC for an inverter with digitally etched nanowires for several supply voltages ranging from 0.25 V to 1V. (b) AC characterization of an inverter circuit operating at 1 kHz at 1 V supply voltage. (c) NAND schematic and (d), NAND circuit operation with a power supply voltage of V_{dd}=1V and a voltage swing of Vᵢₙ=±1 V.

### DETAILED DESCRIPTION

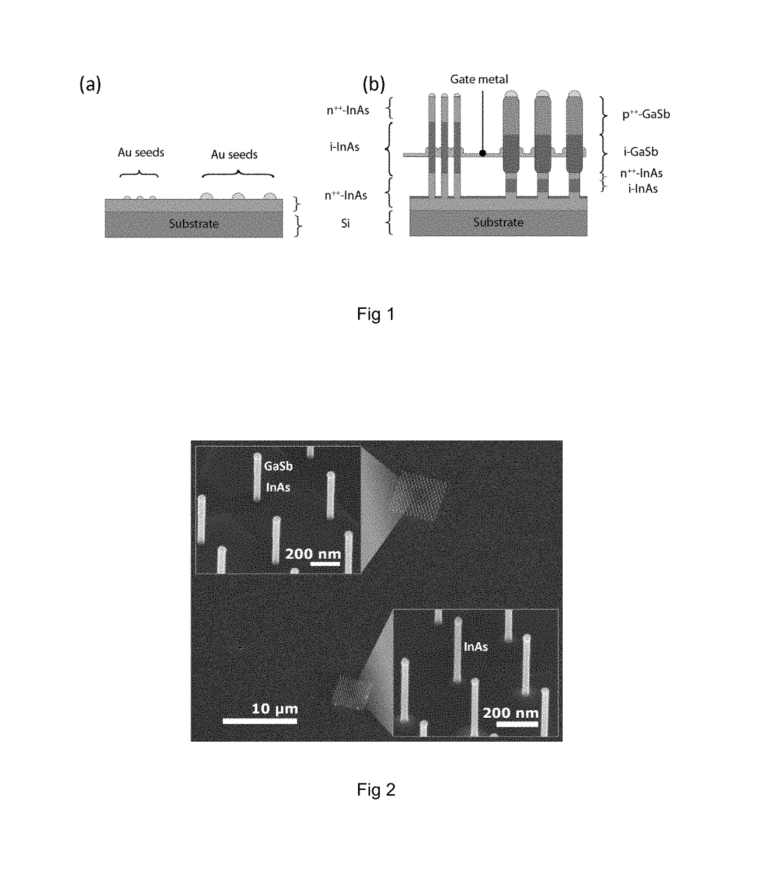

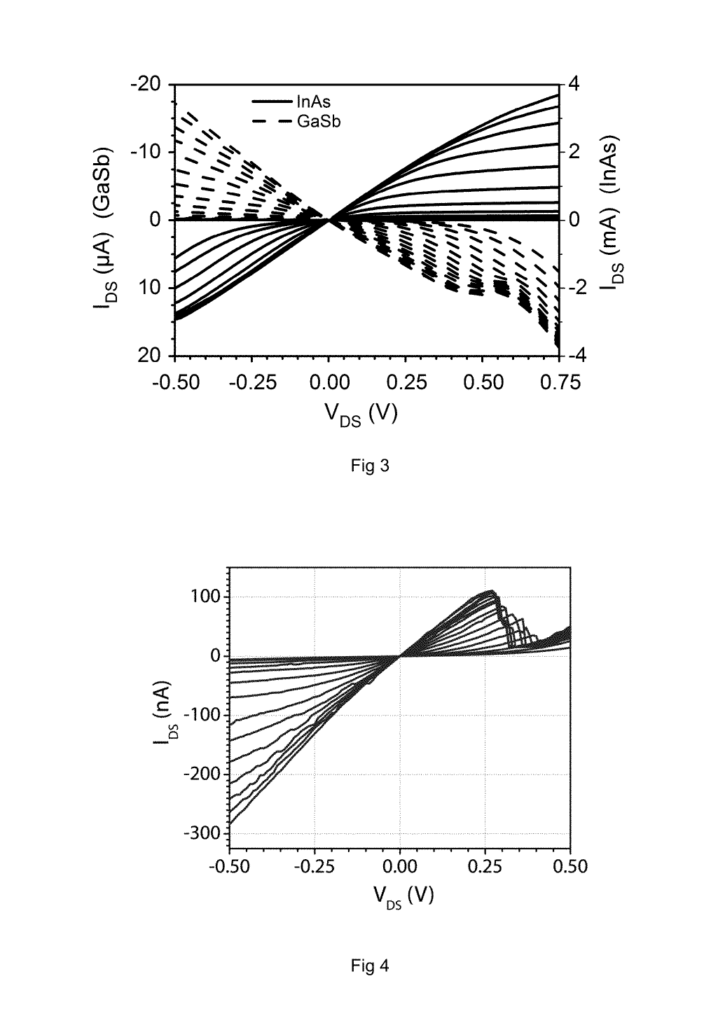

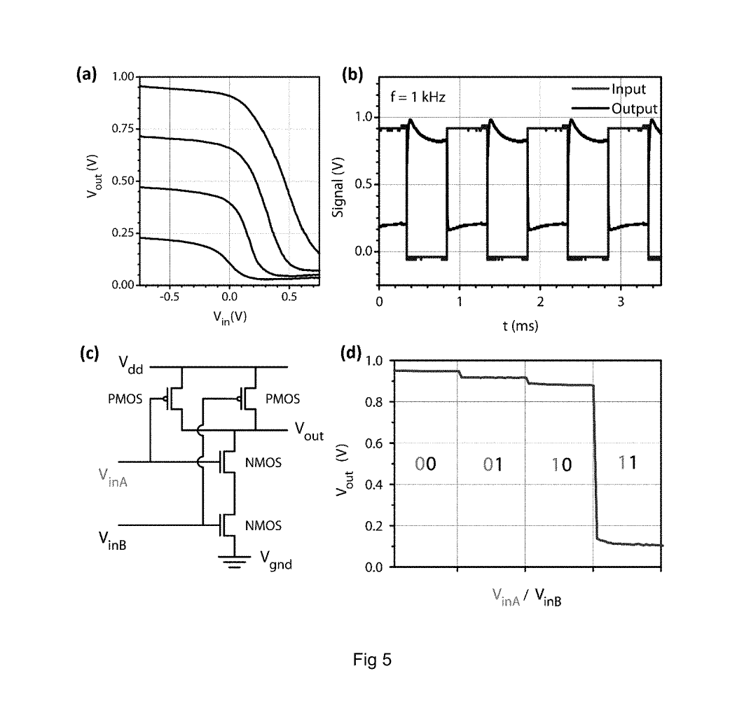

A first method of the present invention relates, in general, to the field of co-integration of complementary nanowire devices fabricated in one growth run, where a growth run includes loading of sample to the reactor, heating to the growth temperature, supply of gases for reactions, cooling of the substrate, and unloading of the sample. A preferred method relates to growth by the vapor liquid solid mechanism, where nanowires of complimentary polarity are grown in one growth run. Such nanowires include n-type InGaAs and InAs and p-type GalnSb and GaSb, but also other materials combinations and alloy compositions may be considered. However, it should be appreciated that the invention is as such equally applicable to other nanowire materials and circuit electronic applications. A second method relates to the growth of complementary nanowires using two growth runs. However, for the sake of clarity and simplicity, most embodiments outlined in this specification are related to the growth of both n- and p-type semiconductor materials on Si by metal-organic vapor phase epitaxy (MOVPE) in a single growth run and the fabrication of MOSFETs with a vertical device architecture and their digital circuit applications. For the sake of clarity, the vertical device architecture consists of parallel nanowires formed perpendicular to the surface, as is evident from the transistor layout presented in FIG. 1b.

Nanowires may in this context refer to semiconductor rods consisting of one single material or alternatively of core/shell nanowires where a second material has been epitaxial grown on the side facets of the first nanowire with the goal of providing enhanced functionality such as strain for transport enhancement or surface passivation. Alternatively we may also consider axial heterostructure nanowires where segments of two different materials have been combined within the nanowire.

The nanowires may be processed into transistors where a dielectric is surrounding the middle of the nanowire and a gate is formed on the dielectric layer. Contacts are made to the nanowire outside the region covered by the gate dielectric and the gate metal forming source and drain electrodes. The contacts can either be ohmic or of other type. Each transistor may consist of one nanowire only, but it may also contain arrays of nanowires, that is a group of nanowires arranged in a pattern and contacted by the same gate and electrodes. The transistors may be connected in various configurations to form circuits consisting of one or more nanowire transistors. Applications can be realized by using one or many transistors, alternatively circuits, which are connected.

Embodiments of the present invention will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference signs refer to like elements throughout.

n-InAs and p-GaSb nanowires are grown by the vapour-liquid-solid mechanism on a Si substrate with electron beam lithography (EBL) patterned Au-particles of different sizes. The size of the Au particles determined the diameter of the nanowires, typically in the range from 3 to 100 nm. An n-type InAs layer is preferable introduced between the Si substrate and the nanowires. The InAs layer is used as a contact to provide low access resistance as we do not introduce any heterostructure barriers between the bottom layer and the nanowires and it may be patterned to provide device isolation and enable high frequency operation. The introduction of an InAs layer thus provides substantial benefits as compared to growth approaches where the nanowires are located directly on the Si substrate. Preferably, p-type substrates are used as the pn-junction between the p-type substrate and the n-type layer reduces the current flow between the n-type layer and the substrate and increases the isolation between devices. The combination of the Si substrate and the InAs layer form a Silicon platform that is used for the growth of the nanowires. It is noteworthy that this platform may be uniform across the complete wafer, although patterning techniques may be used to form local platforms on parts of the wafer. The chemical potential of material dissolved in the Au particle during growth is increased with decreasing particle size due to the higher surface-to-volume ratio. Eventually, the chemical potential approaches that of the gas phase, which reduces the driving force for material transport to the particles what is known as the Gibbs-Thompson effect. Since the solubility for Sb in Au is small, the growth rate of GaSb is highly sensitive to the transport of Sb to the particle and thus for sufficiently small diameters, the growth can be completely suppressed. This can be used for co-integration of InAs and GaSb nanowire arrays on the same Si substrate using a single growth run. In this context we consider nanowires consisting of InAs/GaSb axial heterostructures as a special form of GaSb nanowires.

The nanowires may be grown using metalorganic vapor phase epitaxy (MOVPE) in an Aixtron 200/4 system at a pressure of at 100 mbar and a total flow of 13000 sccm. After annealing at 550° C. in arsine (AsH₃), the InAs segment can be grown at 420° C. using trimethylindium (TMIn) and arsine with a molar fraction of X_{TMin}=2.79·10⁻⁶ and X_{AsH3}=1.92.10⁻⁴, respectively. The sample may be subsequently heated to 460° C. in arsine, where the switch to GaSb growth may be initiated while heating to 500° C. for continued GaSb growth with trimethylgallium (TMGa) and trimethylantimony (TMSb) with a molar fraction of X_{TMGa}=5.79·10⁻⁵ and X_{TMSb}=1.04·10⁻⁶, respectively. In the top part of the GaSb segments diethylzinc (X_{DEZn}=5.99·10⁻⁶) is used for p-doping.

Smaller Au-particles and larger pitches promote a higher axial growth rate of InAs, which can be exploited to precisely control the nanowire length (between 10 and 1000 nm) so that the InAs and InAs/GaSb nanowires reach roughly the same final height. Uniform nanowire length simplifies the processing and device integration as deposited layers, for instance by spin-coating techniques, will have the same thickness and the contacts to the nanowires can be fabricated at the same height above the substrate. These improvements in processing will significantly improve the yield. The number of nanowires in the two types of arrays, can be designed (typically between 1 and 1000) to control the drive current matching between n- and p-type MOSFETs necessary for optimized circuit operation. The number of nanowires can also be changed to achieve impedance matching for RF-devices. In this work, the doping profile along the growth axis of the nanowires has further been engineered to provide a channel where no doping has been introduced and highly doped source/drain regions to reduce the access resistance. Sn or other n-type dopants may be used as the n-type dopant either for only the upper part or for both the lower and upper part of the InAs segment, and Zn is used as the p-type dopant for the upper part or the upper and lower part of the GaSb segment. These dopants are supplied during the growth of the nanowires.

In an alternative method, a technique using two growth runs can be used to enable nanowires of different materials on the same substrate. The process steps include a first step with electron beam lithography (EBL) patterning and evaporation of Au discs of diameters in the range between 3 and 100 nm and acting as nanowire seeds. In a second step they are covered by dielectric film (like SiO2) using processes such as PECVD or HSQ deposition. Openings in the dielectric film is made in a third step in the areas where the Au seeds are located, for instance by using photolithography and wet etching. Subsequently in step four, the first type of nanowires are grown using MOVPE and the dielectric mask is removed in step five. A second set of Au seeds are patterned using EBL in step six, followed by a possible coverage of the grown nanowires in step seven. This step is only needed if the wires would be affected by being exposed to another growth step by e.g. overgrowth or material evaporation. Step eight involves growth of the second type of nanowires from the Au seeds and step nine removal of the second SiO2 mask using diluted HF.

In yet another approach, all Au discs are fabricated in a first step, whereas part of the Au discs are covered by a dielectric film in a second step and the first set of nanowires are grown in step three. Following removal of the dielectric film in step four, the rest of the Au discs are used to grow the second set of nanowires in step five.

Careful engineering of these InAs/GaSb nanowires by means of epitaxy, selective etches, and placement of the gate will significantly alter their electrical properties and is one means of tuning the device characteristics and realize a number of different embodiments.

In one embodiment, two types of nanowires with complementary polarity fabricated by the methods described above are arranged vertically on a Si substrate.

In a second embodiment, the nanowires are arranged on a composite substrate comprising of a p-type substrate with an n-type InAs layer. The InAs-layer is used to reduce the access resistance and may be patterned to provide device isolation. The use of a p-type substrate further helps to improve the isolation. The broken band alignment of InAs and GaSb in combination with the high doping at the interface enables a high tunneling current, where the InAs segment may be used as an ohmic contact to GaSb. Transistors can be fabricated by atomic layer deposition of the gate dielectric and the formation of mesas, spacer layers, metal electrodes and interconnects by means of UV-lithography, wet etching, reactive ion etching and sputtering. The vertical processing does not rely on high resolution lithography, but dimensions are instead defined by control of the deposition layer thicknesses or etch-back of deposited layers, and the gate-all-around architecture allows for aggressive gate length scaling with accurate position.

In a third embodiment, the gate on the GaSb nanowires is aligned for pFET operation and the gate on the InAs is aligned for nFET operation. In this configuration the gate to the GaSb is connected to the GaSb segment only. Alternatively, the gate on the GaSb nanowires is aligned to the InAs/GaSb heterostructure and in a fourth embodiment, an axial TFET may be implemented by direct modulation of the band-to-band tunneling across the heterojunction. In particular, the InAs/GaSb nanowires are grown using the methods described above and they are monolithically connected to the second set of nanowires.

The nanowire transistors described in the embodiments above may be connected to form logic functionality in terms of inverters and NAND gates, these circuits form the fifth embodiment. In this embodiment, the groups of nanowires are grown using the methods described above and they are used as the n- and p-type transistors. Finally, the p-type FETs may be used as active loads connected to the n-type transistors in the sixth embodiment. Both types of nanowires are grown using the above described methods.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

The foregoing has described the principles, preferred embodiments and modes of operation of the present invention. However, the invention should be regarded as illustrative rather than restrictive, and not as being limited to the particular embodiments discussed above. The different features of the various embodiments of the invention can be combined in other combinations than those explicitly described. It should therefore be appreciated that variations may be made in those embodiments by those skilled in the art without departing from the scope of the present invention as defined by the following claims.

1. A method for fabrication of at least two groups of nanowires in one growth run, comprising:
providing a silicon platform; and
growing, in one growth run, at least one group of III-V n-type nanowires and at least one group of III-V p-type nanowires using gold particles, wherein said gold particles are of one size for the III-V n-type nanowires and one size for the III-V p-type nanowires.

2. The method of claim 1,
wherein said gold particles are of one size for the III-V n-type nanowires and one size for the III-V p-type nanowires that is different from the n-type nanowires and where the p-type nanowires contain Sb.

3. The method of claim 1,
wherein the nanowires are arranged in parallel.

4. The method according to claim 1, wherein said silicon platform is comprised of a p-type Si substrate.

5. The method according to claim 1, further comprising the step of providing an InAs layer on said silicon platform.

6. The method according to claim 1, wherein said gold particles have a diameter in the range of 3 to 100 nm.

7. The method according to claim 1, wherein said at least one group of n-type nanowires and said at least one group of p-type nanowires are grown to the same height in the range of 10 nm to 1000 nm.

8. The method according to claim 1, placing at least one metal gate in contact with at least one nanowire in one of said at least one group of n-type nanowires or said at least one group of p-type nanowires.

9. The method according to claim 1, placing at least one metal gate in contact with at least one nanowire in said at least one group of n-type nanowires and at least one nanowire in said at least one group of p-type nanowires.

10. The method according to claim 1, wherein said at least one group of n-type nanowires are n-InAs nanowires and wherein said at least one group of p-type nanowires are p-GaSb nanowires

11. The method according to claim 1, further comprising providing an III-V semiconductor shell around at least one p-type nanowire in said at least one group of p-type nanowires.

12. The method according to claim 11, wherein said III-V semiconductor shell is comprised of InGaAs and/or GalnAsSb.

13. The method according claim 11, wherein said nanowires are axial heterostructure nanowires.

14. A method for fabrication of at least two groups of nanowires, comprising the steps of:
providing a silicon platform;
providing at least two gold discs on said silicon platform;
covering at least one of said discs with a dielectric film;
making an opening in said dielectric film of at least one of said discs;
growing at least one group of either III-V n-type nanowires or at least one group of III-V p-type nanowires using said gold discs;
remove said dielectric film;
provide at least one gold seed to said at least one group of n-type nanowires or said at least one group of p-type nanowires; and
growing at least one group of either III-V n-type nanowires or at least one group of III-V p-type nanowires using said at least one gold seed.

15. A semiconductor device comprising at least one group of III-V n-type nanowires and at least one group of III-V p-type nanowires wherein said at least one group of n-type nanowires and at least one group of p-type nanowires are growing in one growth run according to claim 1.
